(19) United States
(12) Patent Application Publication
(10) Pub. No.: US 2011/0000525 A1
(43) Pub. Date: Jan. 6, 2011

(54) SOLAR ENERGY PANEL FRAME AND INSTALLATION SYSTEM DEVICE THEREOF

(76) Inventors: Wenxiang WU, Taishan City (CN); Weifeng LIU, Taishan City (CN)

Correspondence Address: THE FARRELL LAW FIRM, LLP, 290 Broadhollow Road, Suite 210E, Melville, NY, 11747, US

(21) Appl. No.: 12/829,505

(22) Filed: Jul. 2, 2010

(30) Foreign Application Priority Data
Jul. 3, 2009 (CN) 200910040877

(51) Int. Cl. H01L 31/048

(52) U.S. Cl. 136/251

(57) ABSTRACT

The present invention disclosed a solar energy panel frame and installation system device there of. Said solar energy panel frame includes a frame body which is consist of a plurality of profile brackets abutting joint to each other. Wherein an automatic cleaning device is set on said frame body. And said automatic cleaning device comprises a motor located in the profile bracket symmetrically, a transmission mechanism connected to the output shaft of the motor, a cleaning brush moved in upper and lower direction by said transmission mechanism which it connected to, and a remote control integrated circuit system. Said installation system device of the solar energy panel frame includes a pedestal, a rail bracket which is fixedly connected to the pedestal by a bracket fixing part, and a frame fixing part which is used to lock up the solar energy panel. Wherein said rail bracket is consist of a plurality of profiles having a grooved rail which is on the match usage with above component parts, and said bracket fixing part and said frame fixing part are both eccentric rotary locking solid structure.

### PRIORITY

This application claims priority to an application filed with the Chinese Intellectual Property Office on Jul. 3, 2009 and assigned Serial No. 200910040877.2, the contents of which are incorporated herein by reference.

### BACKGROUND OF THE INVENTION

1. Field of the Invention

The present invention relates to the field of solar energy photovoltaic product technology, and more particularly to solar energy panel frame and installation system device thereof.

2. Description of the Related Art

In these days, as the energy resources are becoming deficient, every country puts forth effort to develop the new energy more and more rapidly. The solar energy, which is a new cleaning energy, plays an important role in the new energy research and development area all over the world. It's known that the basic theory of a solar energy photovoltaic generation is receiving the luminous energy from the outside solar panels, and then transforming the luminous energy to electrical energy by photoelectric reaction for saving to be used.

However, the dust and the bird manure will be accumulated on the surface of the solar panels which are set outdoors, and the winter snow is also accumulated on the surface in winter in the high latitude area. As a result, the light receiving efficiency of the solar panels is low. According to the experiments, the amount of dust accumulated in three months will make the generated energy fall off one third, which will directly cause heavy economic loss. In order to absorb the solar radiation energy fully, the solar panels are fastened to a high place such as a roof and some open places in a general way. However, it's not only hard for cleaning, but also inefficiency and with high costs.

On the other side, the present installation methods of the solar energy panel frame include angle iron joint and standard aluminium profile joint. It's inadvisable to use the angle iron joint on the roof because the angle iron are heavy. It's also needed boring lots of holes both in the angle iron and the solar energy panel frame, which is a difficult procedure and make the angle irons easily rust that can not ensure the duration of service. The standard aluminum profile, which has less weight and a wall with uniform thickness, is used in the standard aluminum profile joint structure. However, in the use of standard aluminum profile, the construction and installation feature of the solar energy panel frame is not taken into account. The installation parts are basically bolts and nuts; punching holes in the frame is needed and the procedure is not only trouble but time-consuming, which undermine the installation's effectiveness.

### SUMMARY OF THE INVENTION

The objective of the present invention is to provide a solar energy panel frame and an installation system device to solve the above-described problems, wherein the solar energy panel frame has a self-cleaning function, and the installation system device is installed conveniently, high efficiently and safely.

To achieve the self-cleaning function objective, the present invention provides the following technical solution.

A solar energy panel frame comprising a frame body which consists of a plurality of profile brackets abutting jointing to each other; wherein an automatic cleaning device is set on said frame body. Said automatic cleaning device comprises a motor located symmetrically in the profile bracket, a transmission mechanism connected to the output shaft of the motor, a cleaning brush driven to move up and down by said transmission mechanism which it connected to, and a remote control integrated circuit system.

As a further improvement of the above-described technology, said transmission mechanism is a screw transmission mechanism comprising a screw drive shaft which is fixedly connected to the output shaft of the motor and a movable sleeve which is hoop-connected to said screw drive shaft and driven by said screw drive shaft. Said screw drive shaft is localized in the profile bracket by a bearing, and one of its ends is fixedly connected to the output shaft of the motor by a pin. A spring and a spring stop are set in the movable sleeve. And said cleaning brush is located on the top of the solar energy panel with its two ends connected to the screw drive shaft separately by said movable sleeve, and the hair and cleaning foil of said cleaning brush touch the surface of the solar energy panel.

As a further improvement of the first-described technology, said transmission mechanism is a sprocket-chain transmission mechanism comprising a first sprocket and a second sprocket which are located on the two ends of the profile bracket separately, a chain which is set on the sprocket, and a fixed connection block which is fixedly connected on the chain. Said first sprocket is fixedly connected to the output shaft of the motor; said cleaning brush is located on the top of the solar energy panel with its two ends fixedly connected to the chain separately by said fixed connection block and the bottom hair and cleaning foil of said cleaning brush touch the surface of the solar energy panel.

As a further improvement of the above-described technology, said automatic cleaning device comprises a spraying unit which comprises a spraying controlled circuit system and spraying pipes. Said spraying controlled circuit system is electrically connected to the remote control integrated circuit system. Said spraying pipes are consisted of a water spraying pipe and a detergent spraying pipe; the intakes of the spraying pipes are connected to the water supply pipe and the detergent supply pipe separately by a electromagnetic valve; and the outlets of the spraying pipe are fixed on the frame body or fixedly located on the cleaning brush by a connection flexible hose.

As a further improvement of the above-described technology, said automatic cleaning device comprises limit switches comprising an upper limit switch and a lower limit switch which are set on the upper end and the lower end of the profile bracket separately and contacted to the transmission mechanism by which the automatic cleaning device is triggered start-up.

As a further improvement of the above-described technology, connectors set on the abutting joint of said profile bracket, and a sealant tape is set on the junction between the profile bracket and the solar energy panel.

To achieve the objective of installing conveniently, high efficiently and safely, the present invention provides the following technical solution.

An installation system device of solar energy panel frame comprising a pedestal; a rail bracket which is fixedly connected to the pedestal by a bracket fixing part; and a frame fixing part which is used to lock up the solar energy panel. Wherein said rail bracket is consisted of a plurality of profiles having a grooved rail which is on the match usage with above component parts, and said bracket fixing part and said frame fixing part are both eccentric rotary locking solid structure.

As a further improvement of the above-described technology, said rail bracket comprises four grooved rails; the first grooved rail is fixedly connected to the pedestal by the bracket fixing part; the second grooved rail is jointed with the frame fixing part; the third grooved rail is fixedly connected to another adjacent rail bracket by a connection locking part; and the fourth grooved rail is a wire casing for housing wires.

As a further improvement of the above-described technology, said bracket fixing part is a first eccentric rotary locking solid structure comparing a “T”-shape connection rod, which have an annular groove in the rod body and one end of the rod body bolt-jointing to a regulating nut; and a penetrating slot bore, which is located in the middle of the pedestal and is fitted to the “T”-shape connection rod; and a first eccentric twist grip which is rotating connected to the pedestal by a bolt bar; a first eccentric cam, which is rotating inserted to said penetrating slot bore and clamped by the annular groove of the “T”-shape connecting rod, is a linking part between the first eccentric twist grip and the pedestal.

As a further improvement of the above-described technology, a clamping safety structure is set on said first eccentric rotary locking solid structure, and the clamping safety structure comprises a locking notch being set in the twist grip and having a circular-arc clamping surface inside and a locking steel ball being fixedly located on the pedestal by a mount pad in which a spring is set inside; the lower part of the locking steel ball being contacted with the top of the spring; and the upper part of the locking steel ball being revealed from the mount pad and being clamped with said circular-arc clamping surface.

As a further improvement of the above-described technology, said bracket fixing part is a second eccentric rotary locking solid structure comparing a second eccentric twist grip, whose connection end is a second eccentric cam; a screw-and-nut subassembly, whose screw body is hitched by a fixed-distance rubber ring, being rotating connected to said second eccentric cam in one end of the screw body, and the nut inserted in the grooved rail of the rail bracket being set on the other end of the screw body; a movable briquetting subassembly, which hitches on said screw body and comprises a square-shaped bottom briquetting and a round-shaped top briquetting, the two briquettings being contacted to each other or integral molded; and a concave groove, in which a concave rubber slab co-used with said second eccentric cam is filled, being disposed on the upper part of the round-shaped top briquetting.

As a further improvement of the above-described technology, a bagging is provided to enwrap the outer of said second eccentric rotary locking solid structure.

As a further improvement of the above-described technology, said connection locking part is a third eccentric rotary locking solid structure which comprises a strip connection profile, being located in the grooved rail between the two adjacent rail bracket; a latching subassembly comprising a latching nut and a latching support bolt jointing fixedly to each other, said latching nut being set in the grooved rail of the rail bracket and corresponding with the position of said strip connection profile; a movable inner briquetting, being set in the latching support; a third eccentric twist grip, being rotation connected with said latching support by a bolt bar, and the connection end between the third eccentric twist grip and the latching support being a third eccentric cam which is co-used with said movable inner briquetting.

As a further improvement of the above-described technology, said pedestal comprises a connection panel and a support movably connected with the connection panel, and the connection panel and the support are integrated to one body by a regulating screw.

Comparing with the prior art, the present invention can achieve the following advantages:

Firstly, to install an automatic cleaning device in the frame is propitious to bring the product performance into full play. This new idea and simple structure lead to low cost and high effects.

Secondly, the invention is designed according to the solar panel's structure and installation feature, which is convenient and time saving. It not only increases the installation's efficiency but has a safety performance, which reduces the cost and saves materials further.

### BRIEF DESCRIPTION OF THE DRAWINGS

FIG. 1 is a structure schematic view of a solar energy panel frame.

FIG. 2 is a structure schematic view of a cleaning device according to a first embodiment of the present invention.

FIG. 3 is a cross-sectional view of the previous said FIG. 2.

FIG. 4 is a structure schematic view of the cleaning device according to a second embodiment of the present invention.

FIG. 5 is a structure schematic view of an installation system device of the solar energy panel frame.

FIG. 6 is a structure schematic view of a rail bracket.

FIG. 7 is a structure view schematically showing the connection structure between a rail bracket and a pedestal.

FIG. 8 is a structure schematic view of a “T”-shape connection rod in FIG. 7.

FIGS. 9a and 9b are structure view schematically showing the state of unlocking and locking of a first eccentric twist grip.

FIG. 10 is a structure view schematically showing the connection structure between a rail bracket and a frame fixing part.

FIG. 11 is a structure schematic view of a frame fixing part locked a solar energy panel frame.

FIG. 12 is a structure view schematically showing the connection structure between a rail bracket and a connection locking part.

FIGS. 13a and 13b are structure view schematically showing the state of unlocking and locking of a third eccentric twist grip.

FIG. 14 is a structure schematic view of a pedestal.

### DETAILED DESCRIPTION OF PREFERRED EMBODIMENTS

The present invention will be described in details with the following embodiments.

The first embodiment is as follows.

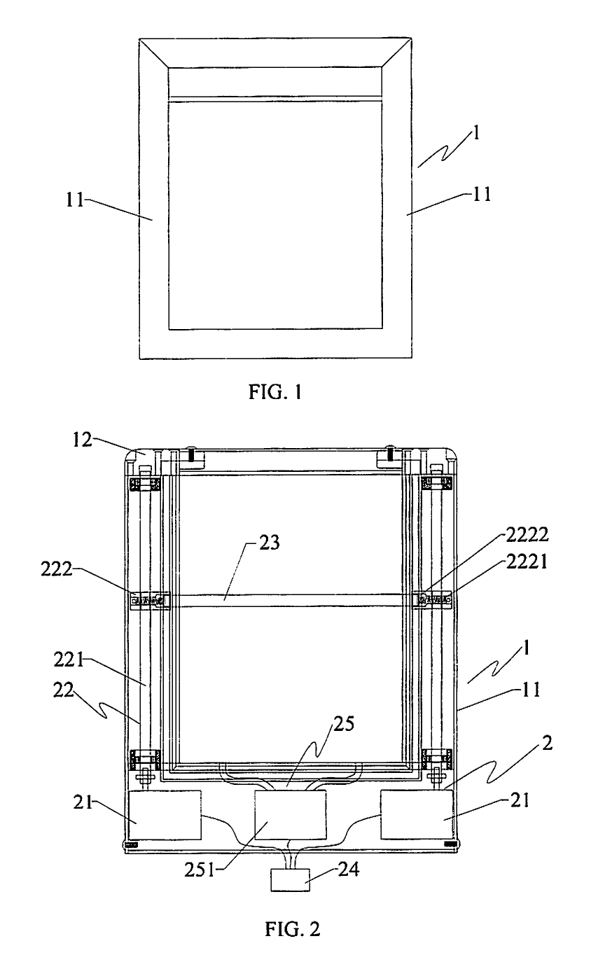

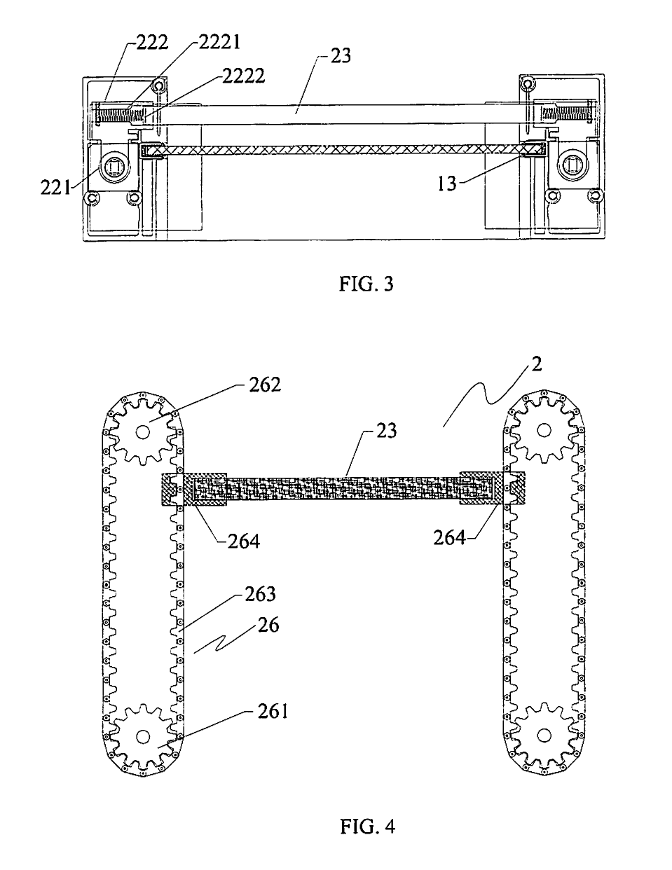

Referring to FIG. 1 to FIG. 3, a solar energy panel frame according to a first embodiment of the present invention includes a frame body 1 which is consisted of a plurality of profile brackets 11 abutting joint to each other. A connector 12 is set on the abutting joint of said profile bracket 11. The connector 12 can be a slab rubber for avoiding a water leakage of the profile brackets 11 in long time exposed to the sun and rain. A sealant tape 13 is set on the junction between the profile bracket and the solar energy panel to prevent dust and water fog in the air to soak in.

Said frame body 1 has an automatic cleaning device 2. The automatic cleaning device 2 includes a synchronous reversible motor 21 set on the profile bracket 11, a screw transmission mechanism 22 driven by the output shaft of the motor, a cleaning brush 23 driven to move up and down by said screw transmission mechanism 22, and a remote control integrated circuit system 24. Said screw transmission mechanism 22 includes a screw drive shaft 221 fixedly connected to the output shaft of the motor and a movable sleeve 222 hoop-connected to said screw drive shaft. The two ends of said screw drive shaft 221 are localized in the profile bracket 11 by a bearing respectively, and one end of said screw drive shaft is fixedly connected to the output shaft of the motor by a pin. A spring 2221 and a spring stop 2222 are set in the movable sleeve 222, which can securely fasten the cleaning brush to heighten the cleaning effect. Said cleaning brush 23 is located above the solar energy panel, its two ends are connected to the screw drive shaft 221 separately by said movable sleeve 222 and its bottom hair and cleaning foil touch the surface of the solar energy panel. When installing the cleaning brush, user just needs to insert two ends of the cleaning brush 23 into the movable sleeve 222, and then push the spring stop 2222 to compress the spring 2221 so that the cleaning brush can be fixed steadily by the resilience force of the spring 2221. The dismantlement work is also easy and convenient as the installation which facilitates procedure in the event of repair or replacement. Meanwhile, an upper limit switch and a lower limit switch are set separately on the upper and lower ends inside the two profile bracket where the screw transmission mechanism is placed, and each of the switches is contacted to the transmission mechanism by which the automatic cleaning device is triggered start-up.

Said automatic cleaning device 2 has a spraying unit 25. The spraying unit 25 includes a spraying controlled circuit system 251 and a spraying pipe. Said spraying controlled circuit system 251 is electrically connected to the remote control integrated circuit system 24. Said spraying pipe includes a water spraying pipe and a detergent spraying pipe. The intakes of the spraying pipe are connected to the water supply pipe and the detergent supply pipe separately by an electromagnetic valve. The outlets of the spraying pipe are fixed on the frame body so that water or detergent can be sprayed regularly to the solar energy panel to achieve a better cleaning effect.

When a large amount of dust, bird manures, snow or other substance cover on the surface of the solar energy panel, just start the synchronous reversible motor 21 set on the profile bracket 11 to rotate the screw drive shaft 221 in the screw transmission mechanism 22. The screw drive shaft 221 doesn't move itself, but the movable sleeve 222 which is connected to the screw drive shaft 221 moves upward or downward as the screw drive shaft 221 rotating, and the cleaning brush 23 moves therewith and cleans the substance on the surface of solar energy panel. When moving to the top or bottom of the profile bracket 11, the cleaning brush 23 touches and starts the upper limit switch or the lower limit switch, and the circuit is switched over so that the cleaning brush 23 move to the opposite direction to keep the cleaning brush 23 moving up and down within the frame. At the same time, said spraying unit 25 opens the electromagnetic valve in the intake of the spraying pipe to spray water and detergent to the solar energy panel surface through the outlets, so that the solar energy panel surface can be cleaned further.

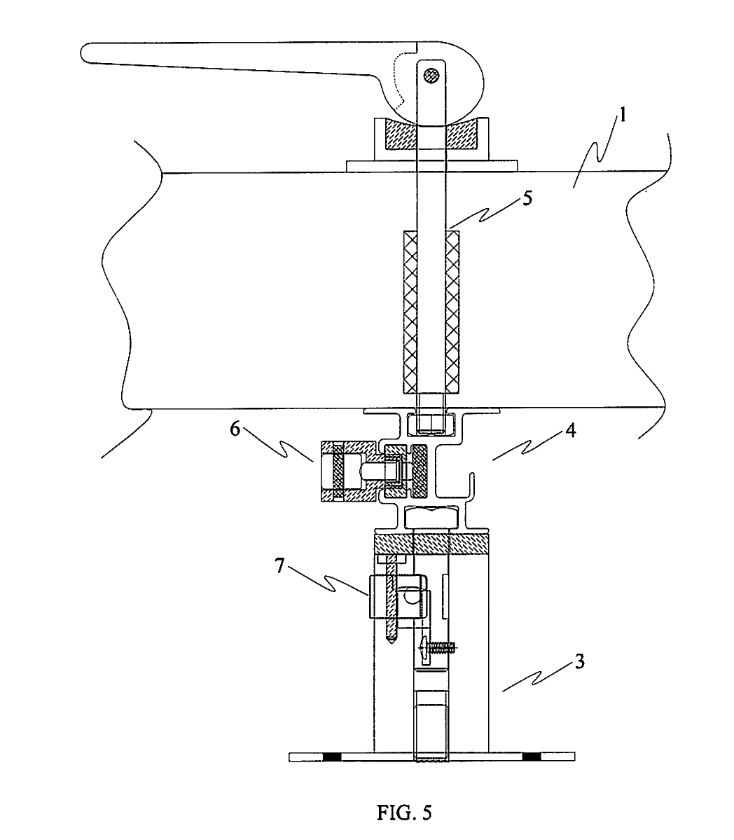

Referring to FIG. 5, an installation system device of solar energy panel frame includes a pedestal 3, a rail bracket 4 which is fixedly connected to the pedestal 3 by a bracket fixing part 7, a frame fixing part 5 which is used to lock up the solar energy panel frame 1, and a connection locking part 6 which is used to fixedly joint two profile bracket adjacent to each other. Said bracket fixing part 7, said frame fixing part 5 and said connection locking part 6 are all eccentric rotary locking solid structure.

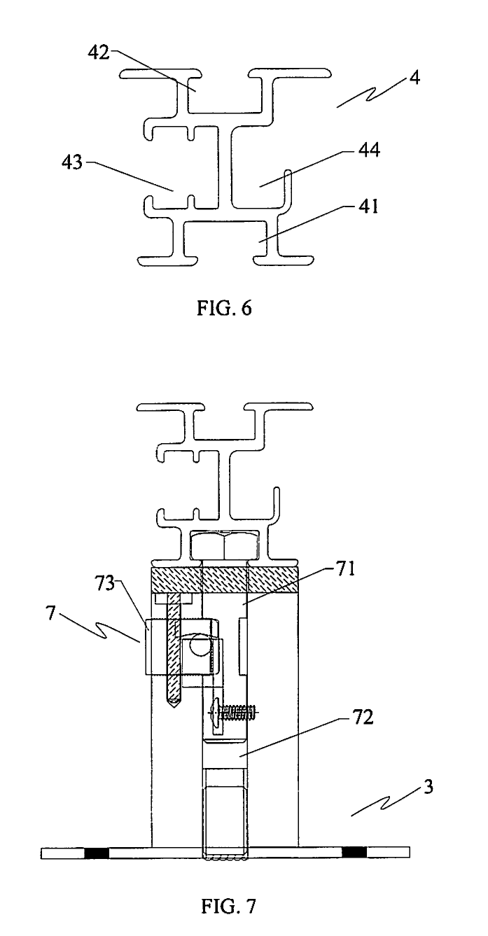

Referring to FIG. 6, said rail bracket 4 includes four grooved rails which are acted in concert with above mentioned parts. The first grooved rail 41 is fixedly connected to the pedestal by the bracket fixing part. The second grooved rail 42 is jointed with the frame fixing part. The third grooved 43 rail is fixedly connected to another adjacent rail bracket by the connection locking part. And the fourth grooved rail 44 is a wire casing for housing wires.

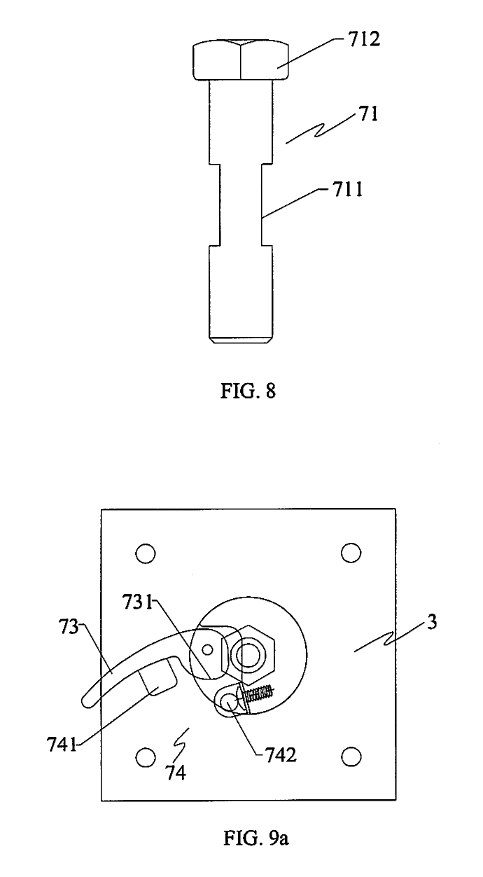

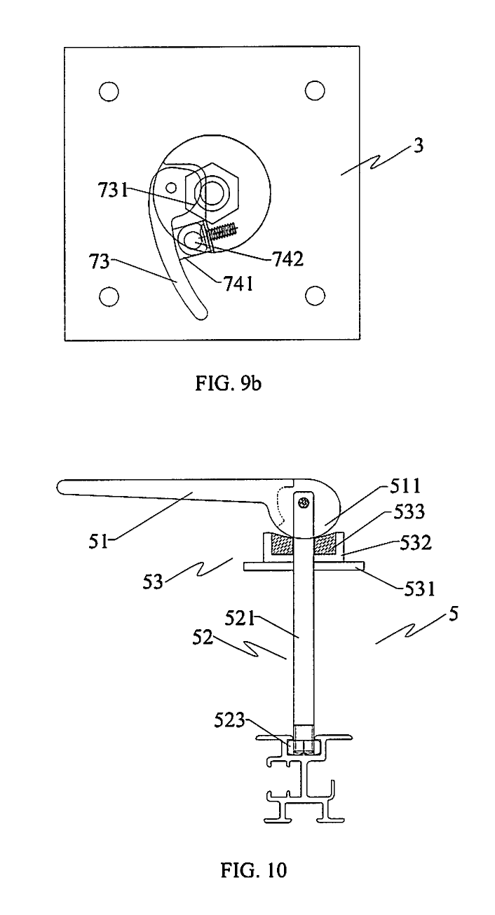

Referring to FIG. 7 to FIG. 9, said bracket fixing part 7 is a first eccentric rotary locking solid structure, and it comprises a “T”-shape connection rod 71, a penetrating slot bore 72 and a first eccentric twist grip 73. The rod body of said “T”-shape connection rod 71 has a annular groove 711, and one end of the rod body bolt-joints to a regulating nut 712. Said penetrating slot bore 72, whose size is fitted to the “T”-shape connection rod 71, is located in the middle of the pedestal. Said first eccentric twist grip 73 is rotating connected to the pedestal 3 by a bolt bar, and its linking part to the pedestal 3 is a first eccentric cam 731 which is rotating inserted to said penetrating slot bore 72 and clamped by the annular groove 711 of the “T”-shape connecting rod.

A clamping safety structure 74 is set on said first eccentric rotary locking solid structure. Said clamping safety structure 74 includes a locking notch 741 and a locking steel ball 742.

Said locking notch 741 is set in the twist grip 73 and has a circular-arc clamping surface. Said clamping safety structure 74 is fixedly located on the pedestal 3 by a mount pad in which a spring is set inside. The lower part of the locking steel ball 742 is contacted with the top of the spring. The upper part of the locking steel ball 742 is revealed from the mount pad and is clamped with said circular-arc clamping surface.

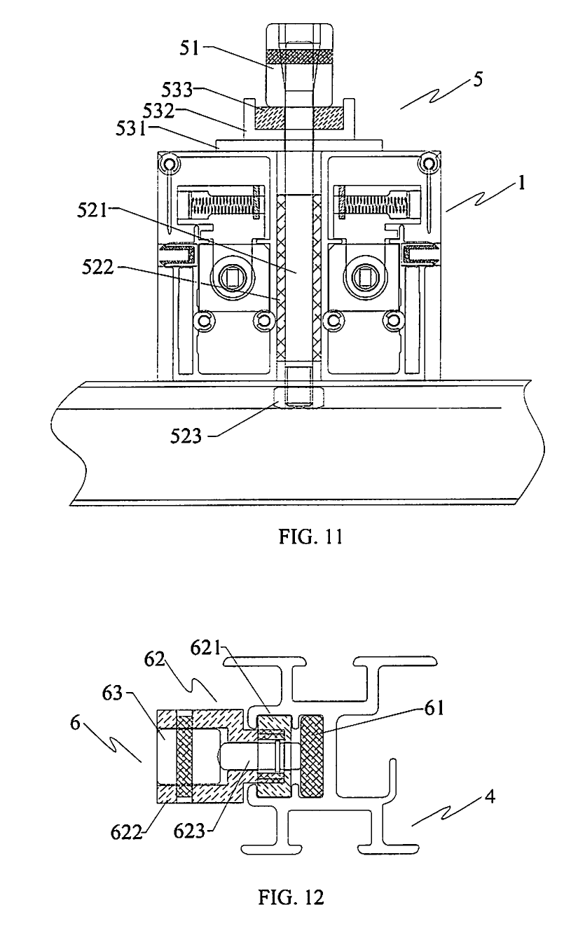

Referring to FIG. 10 to FIG. 11, said bracket fixing part 5 is a second eccentric rotary locking solid structure, which comprises a second eccentric twist grip 51, a screw-and-nut subassembly 52 and a movable briquetting subassembly 53. The connection end of said second eccentric twist grip 51 is a second eccentric cam 511. The screw body of the screw 521 is hitched by a fixed-distance rubber ring. One end of the screw body is rotating connected to said second eccentric cam 511, and the nut 523 inserted in the grooved rail of the rail bracket is set on the other end of the screw body. Said movable briquetting subassembly 53, which is hitched said screw 521, includes a square-shaped bottom briquetting 531 and a round-shaped top briquetting 532. The two briquettings are contacted to each other. A concave groove, in which a concave rubber slab 533 co-using with said second eccentric cam is filled, is disposed on the upper part of the round-shaped top briquetting 532. A bagging enwraps the outer of said second eccentric rotary locking solid structure to prevent it perishing with age exposed to the sun and rain.

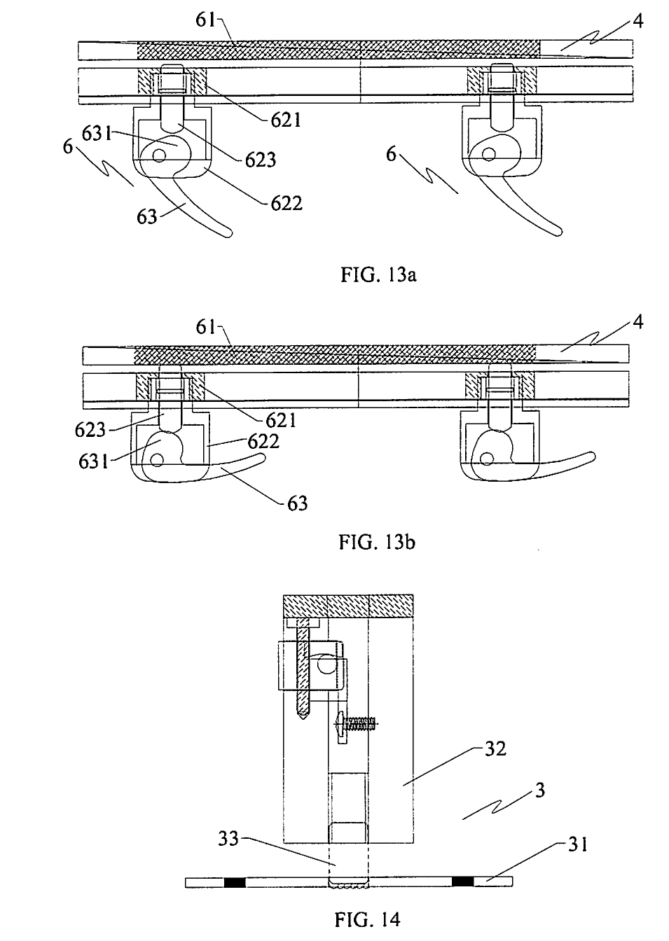

Referring to FIG. 12 to FIG. 13, said connection locking part 6 is a third eccentric rotary locking solid structure which comprises a strip connection profile 61, a latching subassembly 62 and a third eccentric twist grip 63. Said strip connection profile 61 is located in the grooved rail between the two adjacent rail brackets 2. Said latching subassembly 62 includes a latching nut 621 and a latching support bolt 622 jointing fixedly to each other. Said latching nut 621 is set in the grooved rail of the rail bracket and corresponds with the position of said strip connection profile 61. A movable inner briquetting 623 which can extend the latching subassembly to contact with the strip connection profile is set in the latching support 622. Said third eccentric twist grip 63 is rotating connected with said latching support 622 by a bolt bar. The connection end between the third eccentric twist grip and the latching support 622 is a third eccentric cam 631 which is co-used with said movable inner briquetting 623.

Referring to FIG. 14, said pedestal 3 includes a connection panel 31 and a support 32 movably connected with the connection panel 31, and the connection panel 31 and support 32 are integrated to one body by a regulating screw 33. Said regulating screw 33 is bolt jointed with the screw thread in the support 32. It can raise the support 32 to a appropriate height by turning knob the regulating screw 33, which achieves the adjustable aim of the rail bracket's height connecting with the pedestal 3.

Taking the installation on the roof for example, the working principle is as follows:

Firstly, a plurality of pedestal 3 is aligned separately side by side and each connection panel 31 of the pedestal 3 is fixedly connected to the roof by screws. The support 32 is raised to a suitable height by adjusting the regulating screw 33 of the pedestal 3. Repeat the above steps until achieving to a needed desire.

Secondly, the regulating nut 712 of the “T”-shape connection rod 71 of the first eccentric rotary locking solid structure is adjusted and locked into the first grooved rail 41 of the rail bracket 4. The rod body of said “T”-shape connection rod 71 is inserted to the penetrating slot bore 72 of the pedestal 3. The first eccentric cam 731 of the first eccentric twist grip 73 is inserted to said penetrating slot bore 72 and clamped by the annular groove 711 of the “T”-shape connecting rod according to the eccentric theory by rotating the first eccentric first eccentric twist grip 73. Meanwhile, the junction of the locking notch 741 inside the first eccentric twist grip 73 is clamped the a locking steel ball 742 of the pedestal, which locks the first eccentric twist grip 73 further to lock the “T”-shape connection rod 71. So the rail bracket 4 is fixedly connected to the pedestal 3, and the rail bracket 4 using for setting the solar energy panel is located on the roof.

Thirdly, the nut 523 of the screw-and-nut subassembly 52 of the second eccentric rotary locking solid structure is adjusted to a appropriate position, and the tip of the nut 523 is locked into the second grooved rail 42 of the rail bracket 4. Pluralities of said solar energy panel frame 1 which have the automatic cleaning function are located on the rail bracket 4. The screw 521 of the second eccentric rotary locking solid structure has to be disposed between two solar energy panel frames. The movable briquetting subassembly 53 is set on the top of the solar energy panel frame. According the eccentric theory, the concave rubber slab 533 of the round-shaped top briquetting 532 is pressed by the second eccentric cam 511 of the second eccentric twist grip 51 by rotating the second eccentric twist grip 51. So that the solar energy panel frame 1 is firmly pressed by the square-shaped bottom briquetting 531 of the movable briquetting subassembly to ensure the solar energy panel frame 1 is firmly located on the rail bracket 4. A black bagging is enwrapped the outer of said second eccentric rotary locking solid structure to prevent it from aging because of the rain and sun.

Besides, if the roof is so wide that the single rail bracket 4 is not long enough, at least two rail brackets 4 should be connected to extend to an sufficient length. A strip connection profile 61 is inserted into the third grooved 43 of the joint between two adjacent rail brackets 4, and a latching nut 621 of the latching subassembly 62 of the third eccentric rotary locking solid structure is jammed into the third grooved 43 of the joint between two adjacent rail brackets 4 and correspond to the position of a strip connection profile 61. So that the strip connection profile 61 is firmly stuck by the movable inner briquetting 623 which is pushed by the third eccentric cam 631 of the third eccentric twist grip 63 according to the eccentric theory by rotating the third eccentric twist grip 63. Thereby, the two adjacent rail brackets can be connected expediently.

The product of the present invention is an integrated product when leaving the factory. Said solar energy panel has been assembled in the frame already so that there is no size limitation. The size can be designed according to the actual need and the following installation is convenient, saving and efficient.

The second embodiment is as follows.

Referring to FIG. 4, an automatic cleaning device 2 according to a second embodiment of the present invention is similar to the first embodiment. However, the automatic cleaning device 2 in this embodiment includes a synchronous reversible motor 21 set on the profile bracket 11, a sprocket-chain transmission mechanism 26 driven by the output shaft of the motor, a cleaning brush 23 driven to move in up and down by said screw transmission mechanism 22, and a remote control integrated circuit system 24. Said sprocket-chain transmission mechanism 26 includes a first sprocket 261 and a second sprocket 262 which is set on the two ends of the profile bracket separately, a chain 263 set on said two sprockets and a fixed connection block 264 which is fixedly connected on the chain. Said first sprocket 261 is fixedly connected to the output shaft of the motor. Said cleaning brush 23, whose two ends are connected to the chain 263 separately by said fixed connection block 264 and whose bottom hair and cleaning foil are contacted to the surface of the solar energy panel, is located above the solar energy panel.

When a large amount of dust, bird manures, snow or other substance cover on the surface of the solar energy panel, just start the synchronous reversible motor 21 set on the profile bracket 11 to drive the chain of the sprocket-chain transmission mechanism 26 upward and downward, and the cleaning brush 23 moves therewith and cleans the substance on the surface of solar energy panel. When moving to the top or bottom of the profile bracket 11, the cleaning brush 23 touches and starts the upper limit switch or the lower limit switch, which switches over the circuit and makes the cleaning brush 23 move to the opposite direction to make sure the cleaning brush 23 moved within the frame. At the same time, said spraying unit 25 opens the electromagnetic valve in the intake of the spraying pipe to spray water and detergent over the solar energy panel surface through the outlets, which cleans the solar energy panel surface further.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A solar energy panel frame comprising:
a frame body which consists of a plurality of profile brackets abutting jointing to each other;
wherein an automatic cleaning device is set on said frame body, and said automatic cleaning device comprises a motor located symmetrically in the profile bracket, a transmission mechanism connected to the output shaft of the motor, a cleaning brush driven to move up and down by said transmission mechanism which it connected to, and a remote control integrated circuit system.

2. The solar energy panel frame of claim 1, wherein said transmission mechanism is a screw transmission mechanism comprising a screw drive shaft which is fixedly connected to the output shaft of the motor and a movable sleeve which is hoop-connected to said screw drive shaft and driven by said screw drive shaft; said screw drive shaft is localized in the profile bracket by a bearing, and one of its ends is fixedly connected to the output shaft of the motor by a pin; a spring and a spring stop are set in the movable sleeve; and said cleaning brush is located on the top of the solar energy panel with its two ends connected to the screw drive shaft separately by said movable sleeve, and the hair and cleaning foil of said cleaning brush touch the surface of the solar energy panel.

3. The solar energy panel frame of claim 1, wherein said transmission mechanism is a sprocket-chain transmission mechanism comprising a first sprocket and a second sprocket which are located on the two ends of the profile bracket separately, a chain which is set on the sprocket, and a fixed connection block which is fixedly connected on the chain; said first sprocket is fixedly connected to the output shaft of the motor; said cleaning brush is located on the top of the solar energy panel with its two ends fixedly connected to the chain separately by said fixed connection block and the bottom hair and cleaning foil of said cleaning brush touch the surface of the solar energy panel.

4. The solar energy panel frame of claim 1, wherein said automatic cleaning device comprises a spraying unit which comprises a spraying controlled circuit system and spraying pipes; said spraying controlled circuit system is electrically connected to the remote control integrated circuit system; said spraying pipes are consisted of a water spraying pipe and a detergent spraying pipe; the intakes of the spraying pipes are connected to the water supply pipe and the detergent supply pipe separately by a electromagnetic valve; and the outlets of the spraying pipe are fixed on the frame body or fixedly located on the cleaning brush by a connection flexible hose.

5. The solar energy panel frame of claim 1, wherein said automatic cleaning device comprises limit switches comprising an upper limit switch and a lower limit switch which are set on the upper end and the lower end of the profile bracket separately and contacted to the transmission mechanism by which the automatic cleaning device is triggered start-up.

6. The solar energy panel frame of claim 1, wherein connectors set on the abutting joint of said profile bracket and a sealant tape is set on the junction between the profile bracket and the solar energy panel.

7. An installation system device of solar energy panel frame comprising:
a pedestal;
a rail bracket which is fixedly connected to the pedestal by a bracket fixing part; and
a frame fixing part which is used to lock up the solar energy panel;
wherein said rail bracket is consisted of a plurality of profiles having a grooved rail which is on the match usage with above component parts, and said bracket fixing part and said frame fixing part are both eccentric rotary locking solid structure.

8. The installation system device of solar energy panel frame of claim 7, wherein said rail bracket comprises four grooved rails; the first grooved rail is fixedly connected to the pedestal by the bracket fixing part; the second grooved rail is jointed with the frame fixing part; the third grooved rail is fixedly connected to another adjacent rail bracket by a connection locking part; and the fourth grooved rail is a wire casing for housing wires.

9. The installation system device of solar energy panel frame of claim 7, wherein said bracket fixing part is a first eccentric rotary locking solid structure comparing:
a “T”-shape connection rod, which have an annular groove in the rod body and one end of the rod body bolt-jointing to a regulating nut;
a penetrating slot bore, which is located in the middle of the pedestal and is fitted to the “T”-shape connection rod; and
a first eccentric twist grip which is rotating connected to the pedestal by a bolt bar; a first eccentric cam, which is rotating inserted to said penetrating slot bore and clamped by the annular groove of the “T”-shape connecting rod, is a linking part between the first eccentric twist grip and the pedestal.

10. The installation system device of solar energy panel frame of claim 9, wherein a clamping safety structure is set on said first eccentric rotary locking solid structure, and the clamping safety structure comprises:
a locking notch being set in the twist grip and having a circular-arc clamping surface inside; and
a locking steel ball being fixedly located on the pedestal by a mount pad in which a spring is set inside; the lower part of the locking steel ball being contacted with the top of the spring; and the upper part of the locking steel ball being revealed from the mount pad and being clamped with said circular-arc clamping surface.

11. The installation system device of solar energy panel frame of claim 7, wherein said bracket fixing part is a second eccentric rotary locking solid structure comparing:
a second eccentric twist grip, whose connection end is a second eccentric cam;
a screw-and-nut subassembly, whose screw body is hitched by a fixed-distance rubber ring, being rotating connected to said second eccentric cam in one end of the screw body, and the nut inserted in the grooved rail of the rail bracket being set on the other end of the screw body;
a movable briquetting subassembly, which hitches on said screw body and comprises a square-shaped bottom briquetting and a round-shaped top briquetting, the two briquettings being contacted to each other or integral molded; and a concave groove, in which a concave rubber slab co-used with said second eccentric cam is filled, being disposed on the upper part of the round-shaped top briquetting.

12. The installation system device of solar energy panel frame of claim 11, wherein a bagging is provided to enwrap the outer of said second eccentric rotary locking solid structure.

13. The installation system device of solar energy panel frame of claim 8, wherein said connection locking part is a third eccentric rotary locking solid structure which comprises:
a strip connection profile, being located in the grooved rail between the two adjacent rail bracket;
a latching subassembly comprising a latching nut and a latching support bolt jointing fixedly to each other, said latching nut being set in the grooved rail of the rail bracket and corresponding with the position of said strip connection profile; a movable inner briquetting, being set in the latching support;
a third eccentric twist grip, being rotation connected with said latching support by a bolt bar, and the connection end between the third eccentric twist grip and the latching support being a third eccentric cam which is co-used with said movable inner briquetting.

14. The installation system device of solar energy panel frame of claim 9, wherein said pedestal comprises a connection panel and a support movably connected with the connection panel, and the connection panel and the support are integrated to one body by a regulating screw.
